(19) United States
(12) Patent Application Publication
(10) Pub. No.: US 2026/0037711 A1
(43) Pub. Date: Feb. 5, 2026

(54) MANUFACTURE AND LAYOUT ADJUSTMENT OF INTEGRATED CIRCUITS WITH MARGIN ANALYSIS

(71) Applicant: GlobalFoundries U.S. Inc., Malta, NY (US)

(72) Inventors: Collin Arthur Tranter, Clifton Park, NY (US); Navneet K. Jain, Milpitas, CA (US); Romain H.A. Feuillette, Williston, VT (US); David Charles Pritchard, Schenectady, NY (US); Benoit Franois Claude Ramadout, Dresden (DE); Nolan James Pavek, Austin, TX (US)

(21) Appl. No.: 18/792,721

(22) Filed: Aug. 2, 2024

(51) Int. Cl. G06F 30/398; G06F 30/392

(52) U.S. Cl. CPC G06F 30/398; G06F 30/392

(57) ABSTRACT

The disclosure provides a method for the manufacture and layout adjustment of integrated circuits (ICs) with margin analysis. The method includes identifying a design rule applicable to two adjacent structures represented in an integrated circuit (IC) layout. The method also includes predicting, via a machine learning module and an associated library of training data for the IC layout, a margin for the two adjacent structures based on the design rule. From the predicting, the method determines whether the predicted margin is below a threshold margin. In cases where the predicted margin is below the threshold margin, the method includes manufacturing a device from the IC layout. In some implementations, the method includes modifying the IC layout.

### BACKGROUND

The present disclosure relates to integrated circuit (IC) fabrication. More specifically, the present disclosure relates to methods, program products, and systems for controlling IC fabrication.

Fabrication foundries (“fabs”) manufacture ICs using photolithographic processes. Photolithography is an optical printing and fabrication process by which patterns on a photolithographic mask (simply “mask” hereafter) are imaged and defined onto a photosensitive layer coating of a substrate. To manufacture an IC, masks are created using an IC layout as a template. The masks contain the various geometries of the IC layout, and these geometries may be separated with layers of photoresist material.

Through sequential use of the various masks corresponding to a given IC in an IC fabrication process, a large number of material layers of various shapes and thicknesses with different conductive and insulating properties may be built up to form the overall IC and the circuits within the IC layout. Requirements for surface area, structure density, and component size in an IC product may pose technical challenges. Such challenges may include certain design rules (i.e., manufacturing constraints for ensuring manufacturability of a device) imposing stronger limits than necessary for spacing between certain structures within the IC layout. Conventional processing techniques do not allow further modification of a layout for different technical purposes if such modification violates a design rule.

### SUMMARY

Aspects of the disclosure provide a method including: identifying a design rule applicable to two adjacent structures represented in an integrated circuit (IC) layout; predicting, via a machine learning module and an associated library of training data for the IC layout, a margin for the two adjacent structures based on the design rule; determining whether the predicted margin is below a threshold margin; and submitting the IC layout to a manufacturing tool in response to the predicted margin being below the threshold margin.

Further aspects of the disclosure provide a computer program product stored on a computer readable storage medium, the computer program product including program code, which, when being executed by at least one computing device, causes the at least one computing device to: identify a design rule applicable to two adjacent structures represented in an integrated circuit (IC) layout; predict, via a machine learning module and an associated library of training data for the IC layout, a margin for the two adjacent structures based on the design rule; determine whether the predicted margin is below a threshold margin; and manufacture a device from the IC layout in response to the predicted margin being below the threshold margin.

Additional aspects of the disclosure provide a system including: a computing device; an I/O component operatively coupled to the computing device; and a memory operatively coupled to the computing device, wherein the computing device includes logic and is configured to perform a method including: identifying a design rule applicable to two adjacent structures represented in an integrated circuit (IC) layout; predicting, via a machine learning module and an associated library of training data for the IC layout, a margin for the two adjacent structures based on the design rule; determining whether the predicted margin is below a threshold margin; and submitting the IC layout to a manufacturing tool in response to the predicted margin being below the threshold margin.

### BRIEF DESCRIPTION OF THE DRAWINGS

FIG. 1 provides a diagram of adjacent structures within an IC layout according to embodiments of the disclosure.

FIG. 2 provides a schematic diagram of a PDK-based design to improve yield during manufacturing, incorporating a method according to embodiments of the disclosure.

FIG. 3 provides a plan view of an example set of adjacent structures under analysis according to embodiments of the disclosure.

FIG. 4 provides an annotated plan view of the example set of adjacent structures under analysis according to embodiments of the disclosure.

FIG. 5 provides an annotated plan view of the example set of adjacent structures in modified locations according to embodiments of the disclosure.

FIG. 6 depicts a schematic view of an illustrative environment including a computing device for implementing methods according to the disclosure.

FIG. 7 provides a schematic diagram of a machine learning module for margin analysis of integrated circuits according to embodiments of the disclosure.

FIG. 8 provides an example flow diagram for an operational methodology for implementing methods according to embodiments of the disclosure.

FIG. 9 provides an example flow diagram for an operational methodology for implementing methods according to further embodiments of the disclosure.

It is noted that the drawings of the disclosure are not necessarily to scale. The drawings are intended to depict only typical aspects of the invention, and therefore should not be considered as limiting the scope of the invention. In the drawings, like numbering represents like elements between the drawings.

### DETAILED DESCRIPTION

In the following description, reference is made to the accompanying drawings that form a part thereof, and in which is shown by way of illustration specific exemplary embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

The disclosure provides a method for the manufacture and layout adjustment of integrated circuits (ICs) with margin analysis. The method includes identifying a design rule applicable to two adjacent structures represented in an integrated circuit (IC) layout. The method also includes predicting, via a machine learning module and an associated library of training data for the IC layout, a margin for the two adjacent structures based on the design rule. From the predicting, the method determines whether the predicted margin is below a threshold margin. In cases where the predicted margin is below the threshold margin, the method includes manufacturing a device from the IC layout. In some implementations, the method includes modifying the IC layout.

To better illustrate the various embodiments of the present disclosure, particular terminology which may be known or unknown to those of ordinary skill in the art is defined to further clarify the embodiments set forth herein. The term “system” refers to a computer system, server, etc. composed wholly or partially of hardware and/or software components, one or more instances of a system embodied in software and accessible a local or remote user, all or part of one or more systems in a cloud computing environment, one or more physical and/or virtual machines accessed via the internet, other types of physical or virtual computing devices, and/or components thereof. The terms “layout” or “mask layout” refer to a complete or partial mapping of masking material to be used for forming (e.g., by various combinations of etching, deposition, etc.) a particular layer which includes multiple structures (also known as “features”). A “PDK” refers to any user-defined characteristic(s) for distinguishing masks that are viable for manufacture from masks that are not viable for manufacture. PDKs may include a comprehensive listing of such measurements, including for example design structures, dimensions of particular regions, desired amounts of space to be occupied by fill cells, performance requirements, etc., for all measurable aspects of a device to be manufactured.

However, rules in a PDK for determining whether particular layers are compliant or non-compliant with manufacturing requirements are particularly relevant to embodiments discussed herein. In the example of a front end of line (FEOL) layer (i.e., layers of a device formed before the first metallization and including device components such as transistors, resistors, capacitors, etc.), a PDK may include a “mask rule” for the layer to be produced. Mask rules refer to dimensional requirements and other measurements for determining whether a particular mask will cause mask inspection problems. In the example of a back end of line (BEOL) layer, i.e., layers of a device after the first metallization, e.g., layers containing wires and vias for coupling functional components together, a PDK may include a “design rule” for the layer to be produced. Design rules refer to minimum dimensions of devices and interconnects to be formed in an integrated circuit adopted during the design stage and determined by the capabilities of process technology available. Mask rules and design rules are distinct from each other, e.g., by using different types of information about a layout to determine its compliancy or non-compliancy. Mask rules in particular examine an entire mask layout and the spatial relationship between multiple patterns in their final orientation, scale, and tone. In contrast, design rule analysis is usually performed on individual pattern files which may be used to form layouts.

The layout for a particular mask may be obtained from design data and/or generated, modified, etc., with the aid of optical proximity correction (OPC) or other design-enhancement systems. A “structure,” or alternately “feature,” generally refers to a functional element in an IC product (e.g., a wire, waveguide, and/or other element for transmitting electricity, radiation, etc.) which must be printed on a wafer using photolithography techniques. A “region” refers to any subset of a given mask. A “pattern” or “feature pattern” refers to a design layout representation of one or more portions of a mask which define the structures to be formed in a particular IC product, and which may be formed with the aid of a mask by way of, for example, direct-write electron beam lithography. The patterns in a mask may be structured and positioned to cover underlying materials, and thereby protect them from being etched away while other portions of a layer are being removed.

A “margin” refers to an additional amount of distance added to the minimum size of a structure (e.g., length, width, etc., generally known as “critical dimension”) and a separation distance from an adjacent feature along the same dimension to account for process variations when manufacturing the feature(s) in an IC layout. Design rules for an IC layout may prescribe a minimum margin for two adjacent structures based on, e.g., the types of structures being formed and/or the location of those patterns within the IC layout. For each pair of adjacent structures in an IC layout, one or more margins may be calculated for various pairs of structures and/or dimensions. The number of margins and/or directional orientations may differ depending which two adjacent structures are being compared, e.g., an uppermost point on one axis may be used for calculating the margin with an adjacent structure along that axis, whereas a leftmost point or rightmost point on a different axis may be used for calculating the margin for the same structure with a different adjacent structure along that axis.

In modern IC design and manufacture, merely complying with design rules for a product may not include taking advantage of additional opportunities for further compaction of the design, particularly when such compactions still comply with the design rules for an IC layout, because such compactions would violate the margin for two structures. Embodiments of the disclosure provide an additional machine-learning driven analysis to identify opportunities for further compaction of structures within an IC layout by targeting adjacent structures with margins that are too high (i.e., above a threshold margin) and making further modifications to reduce the separation distance between two adjacent structures. In the case where such reductions in separation distance violate a design rule, further processing may include using a library of training data and various machine learning techniques to identify rules that may be modified, and/or other manufacturing restrictions (simply “restrictions” hereafter) that may be relaxed when making a product from a layout. Embodiments of the disclosure thereby produce various technical effects, etc., products that are manufactured to include a higher structure density than would otherwise be possible through conventional design rule check (DRC) and optical proximity correction (OPC) techniques.

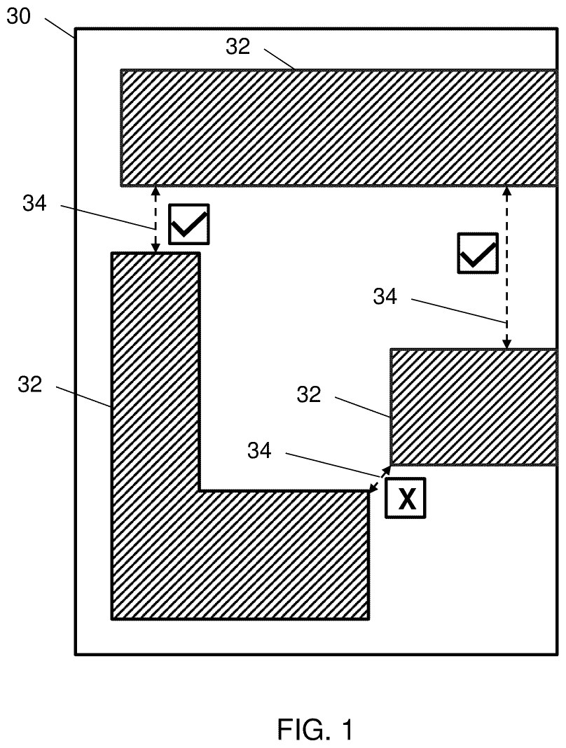

FIG. 1 illustrates a plan view of an IC layout (“layout” hereafter) 30 in plane X-Y, representing at least a portion of a mask to be used in the manufacture of one or more devices. Layout 30 may encompass a given surface area in plane X-Y, and only a portion of layout 30 is shown in FIG. 1 to better illustrate various aspects of structures 32 that may be included within layout 30. Layout 30, furthermore, depicts only one layer of an IC product to be manufactured. Other layers of the same product may be depicted in separate layers, and thus, certain structures 32 in layout 30 that appear to be isolated from each other may be interconnected through other structures that appear in different layers but are not depicted in layout 30.

At a high level of generality, layout 30 may include any combination of structures 32, each of which may have any conceivable shape and/or size. Various structures 32, for example, may represent transistors, capacitors, resistors, waveguides, inductors, wires, diodes, etc. Although structures 32 are shown by example as having essentially linear edges, it is understood that in various implementations one or more structures 32 of IC layout 30 may include curvilinear edges, shapes, etc., and the linear edges of structures 32 shown are solely for ease of illustration. Methods of the disclosure pertain to analyzing structures 32 in layout 30 (including those already deemed compliant with design rules) to identify opportunities for compaction of structures 32 within layout 30, and manufacturing any layouts modified for compaction of structures 32 where possible.

FIG. 1 also depicts separation distances 34 between adjacent structures 32. Structures 32 are considered “adjacent” if a line connecting a reference point from one structure 32 to another reference point of another structure 32 does not pass through any structures 32 located therebetween. Each separation distance 34 does not indicate physical space on a manufactured product, but rather, is a prediction for the amount of physical distance between adjacent structures 32 based on design rules for layout 30. It is understood that some structures 32 may not be adjacent along one connecting line but may be considered adjacent along one or more other connecting lines. In the illustrated example, structures 32 of layout 30 are pre-determined (e.g., in earlier, conventional phases of processing and/or analysis) to be compliant with applicable design rules for a product to be manufactured. Some separation distances 34 in layout 30 are indicated with check marks whereas another separation distance 34 is indicated with an X mark to indicate whether the margin for each separation distance 34 is below (i.e., X mark) or not below (i.e., check mark) a threshold margin value. In various implementations, the threshold margin value can be user selected to be a particular value (e.g., fifty nanometers (nm)), calculated from design rules for layout 30, and/or combinations for choosing a threshold margin between structures 32.

In the context of this disclosure, the “threshold margin” is different from a “minimum separation” between structures. “Minimum separation” refers to the smallest possible distance between adjacent structures 32 in layout 30 while maintaining manufacturability. The minimum separation may be defined by physical parameters of any tools, equipment, etc., for manufacturing a product from layout 30. Threshold margin by contrast refers to an estimated additional distance, greater than the minimum separation distance, to account for process variations when manufacturing a device from layout 30. Embodiments of the disclosure consider whether, by changing or relaxing some margins, compaction of adjacent structures 32 is possible without violating the minimum separation for layout 30. With continued reference to examples herein, a threshold margin of approximately fifty nm may correspond to a minimum separation of approximately thirty nm. Thus, a margin that is not below the threshold margin indicate opportunities to change the position of structures 32 to make layout 30 more compact without violating the minimum separation between structures 32 within layout 30. All separation distances 34 in layout 30 have at least a minimum magnitude (e.g., determined in preliminary phases of processing separate from methods of the disclosure). The margin can then be calculated from each separation distance 34. Any calculated margins not below the threshold margin (i.e., those indicated with checkmarks) are locations where structures 32 could be moved closer together. Any separation distances 34 below the threshold margin (i.e., those indicated with X signs in layout 30) are locations where structures 32 may not be moved closer together without violating design rules for layout 30.

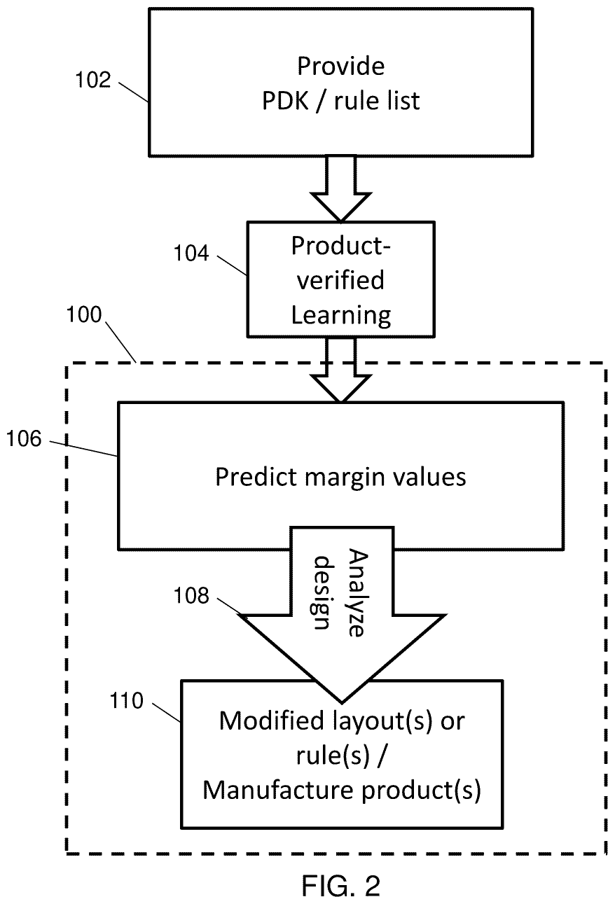

Referring to FIGS. 1 and 2 together, in which FIG. 2 depicts a schematic diagram of a process design kit (PDK) based manufacturing technique incorporating a method 100 to form a product from layout 30 according to embodiments of the disclosure, various operational details are discussed. Before method 100 is implemented, preliminary operations may include operation 102 of providing (e.g., creating or otherwise obtaining) a PDK and/or design rule list for a product to be manufactured and/or operation 104 to perform product-verified learning of how and/or whether any test devices manufactured via the PDK and/or design rule list correspond to the parameters therein. The creating or providing of a PDK and/or rule list in operation 102 may be according to any currently known or later developed technique for providing a PDK for a product. For instance, PDK(s) provided in operation 102 may include, without limitation: a library of device data (e.g., parameters, cell types and locations, etc.), verification standards (e.g., design rule check (DRC) information, antenna and electrical rule checks, physical extraction information, etc.), manufacturing validation data (e.g., various attributes of devices formed from layouts, including differences between design parameters and actual products), device data (e.g., layers, electrical rules, processing data, color-based lithography models, etc.), rule files (e.g., libraries of design rules for a particular product, which may be included within and/or separate from the PDG), simulation models (e.g., simulated parameters of components such as transistors, capacitors, resistors, current and/or voltage sources, inductors, aggregated components such as amplifiers, logic gates, etc.), previously predicted margin information, as well as other information such as cell libraries, vendor information and part serial numbers, manufacturing tool information, etc.

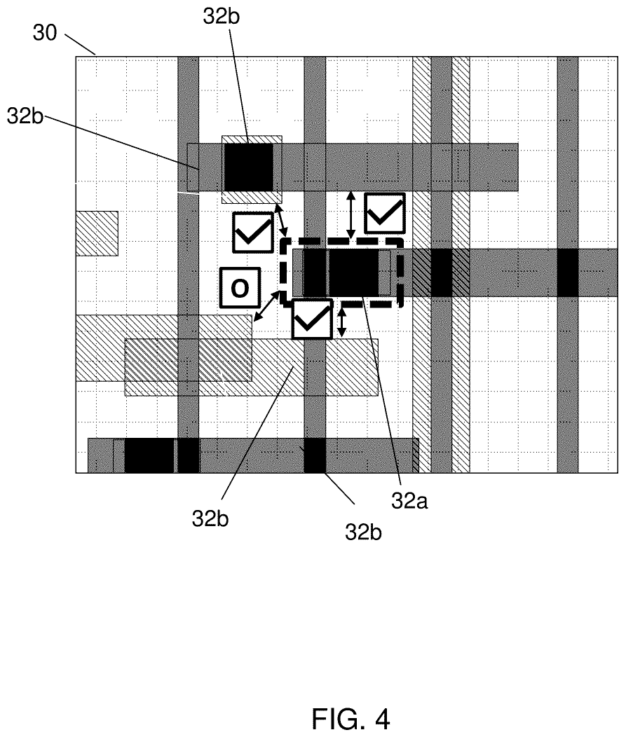

Operation 104 may include, e.g., designing one or more products or test products via the PDK and/or rule list provided and/or created in operation 102 and manufacturing such products or test products. Operation 104 thus may include any currently known or later developed technique for creating a training data repository for further adjustment and/or modification of PDK, etc., by comparing various models and/or rules to actual products, devices, etc., created from such kits and/or rules. The “product verified learning” in operation 104 thus may refer to silicon validation and/or other conventional processes to update and/or expand available training data for modeling the manufacture of other products from the same PDK and/or other PDKs. After operation 104 concludes, various physical parameters reflecting the relationship between PDK and/or design parameters and products manufactured therefrom may be organized and provided within a library or other training data repository (i.e., library 280 (FIG. 4) discussed herein) and used for further modifying of layout 30 and/or training a system to make layout 30 more compact as method 100 is implemented. In some implementations, operation 104 may be implemented multiple times but the total number implementations may be intentionally limited, i.e., by replacing additional implementations with predicting of margin size and further adjusting of layout 30 to reduce the size of separation distances 34 and predicted margins where possible as discussed herein.

Method 100 may include operation 106 of predicting the value of one or more margins within layout 30. The predicting in operation 106 may be subdivided into multiple individual steps and/or repeated iterations, e.g., based on information within a particular layout 30, PDK, rule list, etc., as well as any product-verified data within a training library and/or yielded from operation 104. When operation 106 concludes, layout 30 may be appended with data for each structure therein, e.g., each pair of adjacent structures 32 become associated with a predicted separation distance 34 having a particular value based on the data and/or models for implementing the prediction in operation 106. Operation 108 may include further analyzing layout 30, structures 32, and separation distances 34 to predict whether their margin(s) is/are below a threshold margin, and further determining whether separation distances 34 may still comply with the PDK and/or rule list provided in operation 102. Layout 30 or portions thereof may be marked (e.g., flagged internally as part of an associated data matrix) as both compliant with design rules and capable of further compaction in some cases. Other layouts 30 and/or portions thereof may be marked as non-compliant with design rules, or as compliant with design rules but not being capable of further compaction within layout 30. Method 100 thus may include operation 110 in which, from the analysis conducted in operation 108, modified design rules and/or layouts 30 may be proposed or manufactured to further condense the surface area occupied by structures 32 in layout 30.

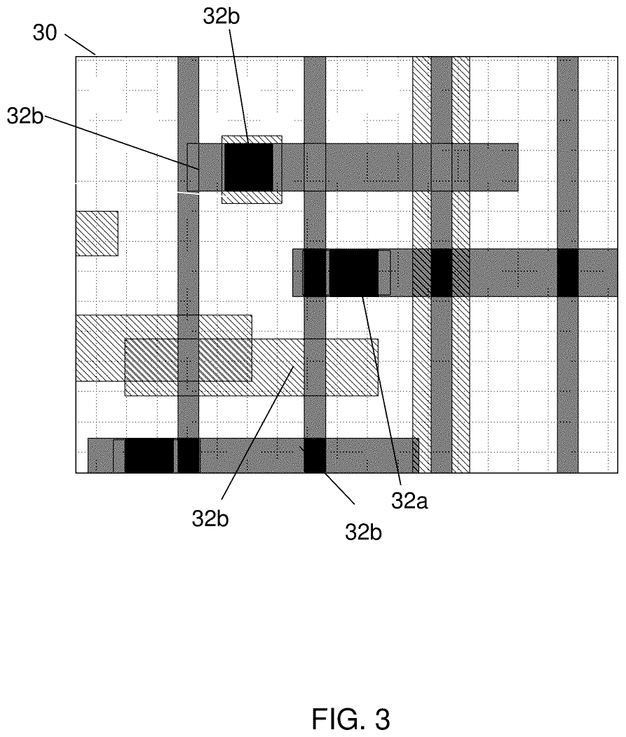

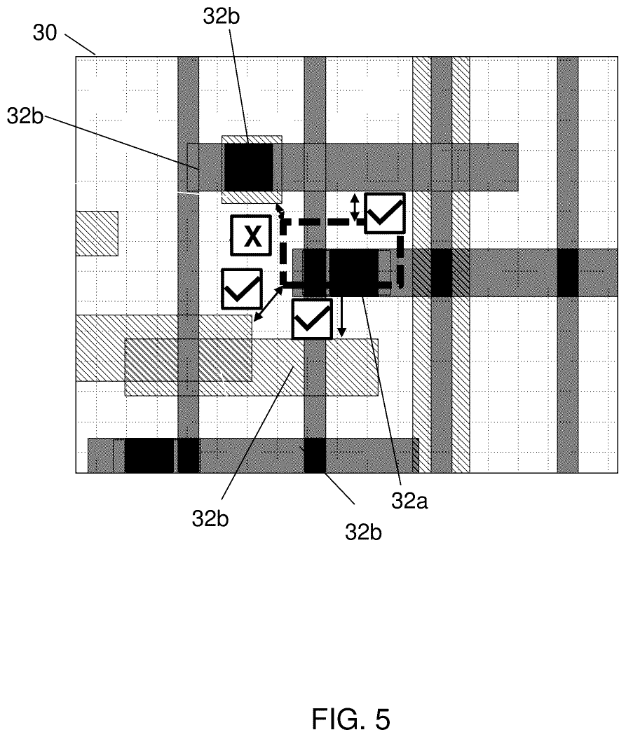

FIGS. 3-5 depict an example of method 100 being implemented on a portion of layout 30. It is understood that the portion of layout 30 shown in FIGS. 3-5 is an example design where embodiments of the disclosure may be implemented, and moreover, that embodiments of the disclosure may be implemented on multiple portions of layout 30 having any size and/or number of structures 32 simultaneously, sequentially, etc. Layout 30 may include a structure under analysis 32a (“analysis structure”) and several adjacent structures 32b. Any structure 32 may be an analysis structure when implementing method 100; analysis structure 32a is identified as such solely because it is being compared with adjacent structures 32b, and not because of any other distinguishing characteristics. FIG. 3 depicts layout 30 with structures 32a, 32b as initially set forth in a particular design. FIG. 4 depicts layout 30 under initial phases of analysis (e.g., operation 106 (FIG. 2) discussed herein), and FIG. 5 depicts hypothetical changes to layout 30 proposed in operations 108, 110 (FIG. 2) in further processing.

Referring specifically to FIG. 4, the position of analysis structure 32a, once chosen, in layout 30 is compared with adjacent structures 32b. The comparison may incorporate a variety of spatial attributes within layout 30 including, e.g., the actual separation distance, the separation distance required in design rules, the threshold separation distance for compaction, parasitic resistance and capacitance for analysis structure 32a in layout 30, etc. In the example of FIG. 4, four adjacent structures 32b are examined to determine whether further compaction is possible. Three adjacent structures 32b are indicated with check marks for having margins compliant with design rules for layout 30, and above the threshold margin for margins between analysis structure 32a and adjacent structures 32b.

During analysis, adjacent structures 32b with a threshold margin of approximately thirty-one nanometers (nm) may have a separation distance of thirty-four nm (upper left adjacent structure 32b), or seventy-seven nm (rightmost adjacent structure 32b). Other adjacent structures with different threshold margin distances also may be eligible for further compaction, e.g., the upper adjacent structure 32b may have a threshold margin of twenty-four nm and a separation distance of forty-six nm. Thus, further compaction of these adjacent structures 32b is possible so long as the compaction does not violate any design rules (e.g., minimum separation) for layout 30. Another adjacent structure 32b to the lower left of analysis structure 32a, by contrast, may have margin of approximately thirty nanometers, which may be greater than the minimum separation (e.g., seventeen nm) but less than the threshold margin (e.g., thirty-one nanometers). Thus, this adjacent structure 32b is denoted with an “O” symbol to indicate that it complies with design rules, but that further compaction poses a risk of violating design rules due to its margin being less than the threshold margin.

Continuing to FIG. 5, methods of the disclosure consider whether changing the position of analysis structure 32a relative to adjacent structures 32b will retain compliance with design rules and/or provide further compaction of space between analysis structure 32a and adjacent structures 32b. In this example, analysis structure 32a is moved upward and its separation from adjacent structures 32b is reconsidered. In this example, this change in position will violate design rules because the separation analysis structure 32a and adjacent structure 32b to the upper left becomes sixteen nm, which is less than the minimum separation (e.g., seventeen nm) for layout 30. The violation of design rules is indicated with an “X” symbol within layout 30.

Notwithstanding the violation of a design rule, further analysis of layout 30 continues to analyze whether compaction is possible in other directions. Here, adjacent structures 32b to the lower left, north, and south of analysis structure 32a are now indicated with check marks for having separation distances above the minimum separation and threshold margins for layout 30. In addition, the separation between analysis structure 32a and adjacent structure 32b to its north is now indicated with an “O” symbol for being above the minimum separation for that particular adjacent structure 32b (i.e., fourteen nanometers) but less than the threshold margin (e.g., twenty-three nanometers relative to a threshold margin of twenty-four nanometers). Although these modifications do not create a manufacturable layout 30, they may become training data for further analysis of layout 30 in other locations, and/or for analysis of other layouts 30, to more easily determine whether compaction of space between structures 32 is possible. The portion of layout 30 can also be modified in other ways, e.g., analysis structure 32a could be moved to the right instead of upward and re-analyzed for compliance with design rules and whether any separation with adjacent structures 32b is less than the threshold margin. In any case where analysis of layout 30 predicts a margin between analysis structure 32a and adjacent structures 32b that is less than the threshold margin for all adjacent structures 32b, the layout 30 and/or portion thereof under analysis may be considered manufacturable without further compaction being possible. It should be understood that the values (e.g., in nanometers) of threshold margins and separation distances, which are mentioned above in the discussion of FIGS. 3-5, are example values. These example values are provided for illustration only and are not intended to be limiting. Those skilled in the art will recognize that such values will depend upon the technology node, the processing layer(s), the materials of the analysis structure and an adjacent structure, materials between the analysis structure and adjacent structure, parasitics, etc.

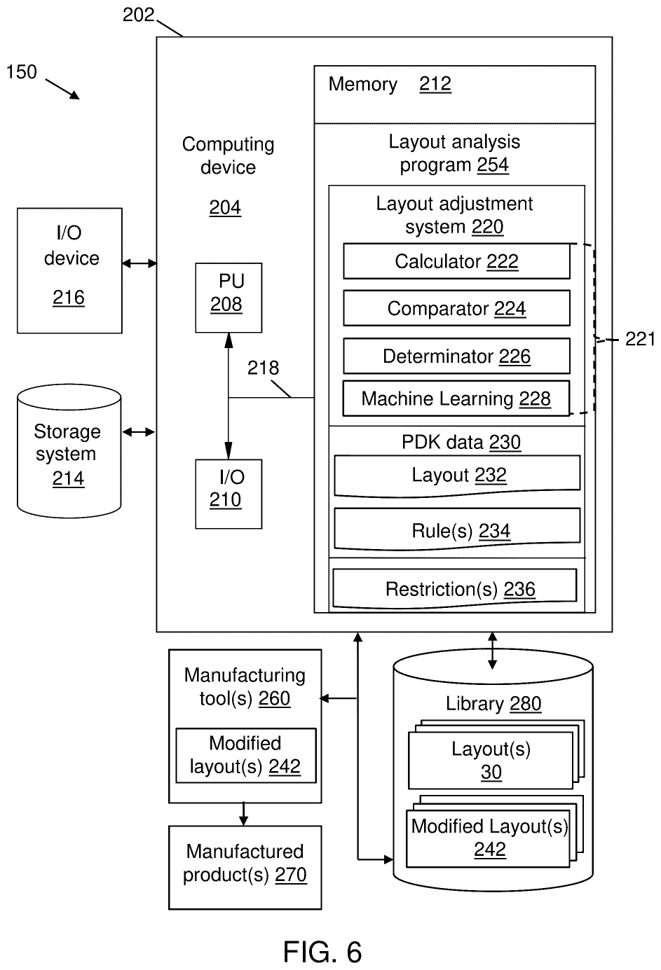

Referring to FIGS. 1 and 6 together, an illustrative environment 150 (FIG. 6 only) for implementing the methods and/or systems described herein is shown. In particular, a computer system 202 is shown to include computing device 204. Computing device 204 may include, e.g., a layout analysis program 254 which may include, e.g., one or more sub-systems such as layout adjustment system 220, for performing any/all of the processes described herein and implementing any/all of the embodiments described herein.

Environment 150 may include manufacturing tool(s) 260 (e.g., a single manufacturing tool and/or a group of interconnected devices) configured to create manufactured mask(s) 270 from modified layout(s) 242 (i.e., layout(s) 30 modified in embodiments of method 100 discussed herein). Manufactured mask(s) 270 may be manufactured from modified layout(s) 242 having structures 32 in positions that are closer together than an initial, non-modified version of layout(s) 30 while retaining compliance with any rule(s) 234 specified in PDK data 230. Environment 150 may also include a library 280 for storing layout(s) 30 and/or modified layout(s) 242. In accordance with embodiments of the disclosure, library 280 is connected to and modified by a layout analysis program 254 including, e.g., one or more systems for creating modified layout(s) 242 from layout(s) 30. Layout analysis program 254 may be implemented, e.g., in a computer system 202, and the various systems and modules therein may operate through one or more processing techniques described herein. Layout analysis program 254 may select particular layout(s) 30 for analysis and to change the position of structures 32 in layout(s) 30 to create modified layout(s) 242 as discussed herein. Computer system 202 may be in communication with library 280, e.g., according to any currently-known or later developed solution for communicating between data repositories (e.g., library 280), computer systems (e.g., computer system 202), and/or other data repositories discussed herein.

Computer system 202 can aid in the design and manufacture of IC products by causing manufacturing tool(s) 260 to create manufactured mask(s) 270 from layout(s) 30 and/or modified layout(s) 242, and/or converting one or more layout(s) 30 into modified layout(s) 242. The modifying of layout 242 may be accomplished by changing the position of certain structures within layout 30 to reduce the separation distance between adjacent structures. The modifying layout 242 in addition or alternatively may include changing rule(s) 234 and/or restriction(s) (e.g., additional requirements for manufacturability not taking the format of rule(s) 234 in PDK data 230, e.g., allowing the margin to be changed or even violated in some locations). Modified layout(s) 242, when created and/or applicable, may occupy less surface area than the initial layout(s) 30 by moving adjacent structures closer together Layout analysis program 254 may perform functions discussed herein, e.g., by processing data from library 280 for one or more layouts 30. Layout analysis program 254 may generate instructions for adjusting manufacturing tool(s) 260, based on the location of structures in modified layout(s) 242. Modified layout(s) 242 may be stored, e.g., in memory components of computer system 202 for future use. Example procedures for modifying layout 30 to create modified layout 242 are provided in further detail below.

Computer system 202 is shown including a processing unit (PU) 208 (e.g., one or more processors), an I/O component 210, a memory 212 (e.g., a storage hierarchy), an external storage system 214, an input/output (I/O) device 216 (e.g., one or more I/O interfaces and/or devices), and a communications pathway 218. In general, processing unit 208 may execute program code, such as layout analysis program 254, which is at least partially stored in memory 212. While executing program code, processing unit 208 may process data, which may result in reading and/or writing data from/to memory 212 and/or storage system 214. Pathway 218 provides a communications link between each of the components in environment 150. I/O component 210 may include one or more human I/O devices, which enable a human user to interact with computer system 202 and/or one or more communications devices to enable a system user to communicate with the computer system 202 using any type of communications link. To this extent, layout analysis program 254 may manage a set of interfaces (e.g., graphical user interface(s), application program interface(s), etc.) that enable system users to interact with layout analysis program 254. Further, layout analysis program 254 may manage (e.g., store, retrieve, create, manipulate, organize, present, etc.) data, through several modules contained within a layout adjustment system 220. Layout adjustment system 220 is shown by example as being a sub-system of layout analysis program 254.

As noted herein, layout analysis program 254 may include layout adjustment system 220. In this case, various modules (calculator 222, comparator 224, determinator 226, machine learning 228, and collectively “modules”) of layout adjustment system 220 may enable computer system 202 to perform a set of tasks used by layout analysis program 254 and may be separately developed and/or implemented apart from other portions of layout analysis program 254. Calculator 222 can implement various mathematical computations in processes discussed herein. Comparator 224 can compare two quantities and/or items of data in processes discussed herein. Determinator 226 may, e.g., make logical determinations based on compliance or non-compliance with various conditions in processes discussed herein. Machine learning module(s) 228 may implement various mathematical, logical, and/or data storage and retrieval functions in combination to provide machine learning functions discussed herein. That is, machine learning 228 allows layout analysis program 254 to automatically create and/or modify various analysis techniques within method(s) 100 discussed herein. One or more modules 222, 224, 226, 228 may use algorithm-based calculations, look up tables, software code, and/or similar tools stored in memory 212 for processing, analyzing, and operating on data to perform their respective functions. Each module discussed herein may obtain and/or operate on data from exterior components, units, systems, etc., or from memory 212 of computing device 204.

Layout analysis program 254 may also include a catalogue of data, rules, and/or other aspects of a product to be manufactured, expressed as PDK data 230 which defines acceptable design characteristics and manufacturing parameters for layout(s) 30. PDK data 230 may include various fields, e.g., a layout 232 field for cataloguing one or more layouts 30 certain products, rules 234 in the form of a listing of metrics for evaluating whether the design of each layout 30 is acceptable (based on parameters such as, e.g., structure size, structure width and/or length, margin size, etc.) for defining minimum and/or maximum physical parameters for structures in layout 30. Other types of rules 234 and/or parameters for comparison, where desired or applicable, also may be included in PDK data 230. Other rules and/or forms of reference measurements, values, etc., may additionally or alternatively be stored in different fields of PDK data 230. Restrictions 236 (also known as manufacturing restrictions) may be additional prohibitions on layout 30 characteristics that are imposed externally on PDK data 230 by layout analysis program 254 and may be specific to only one PDK data 230 and/or subset of PDKs data 230 without being generalized rules for any product and/or group of products to be manufactured. Layout adjustment system 220 and modules 222, 224, 226, 228 thereof may cross-reference and apply data within PDK data 230 to implement various processes according to the disclosure, e.g., determining whether certain adjacent structures in layout(s) 30 have margins not below a threshold margin, and in such cases, changing the position of structures in layout(s) 30 to provide reduced margins and thus provide modified layout(s) 242.

In addition to working in conjunction with PDK data 230, layout adjustment system 220 may manipulate, interpret, and analyze various forms of information in library 280, including one or more existing layout(s) 30 for one or more individual mask layers or products. In addition, layout adjustment system 220 may generate modified layout(s) 242 to enable manufacturing of modified layout(s) 242 in library 280. In further embodiments, layout analysis program 254 may generate a set of instructions which in turn create modified layout(s) 242 from layout(s) 30 on library 280. Library 280 may form part of, or otherwise may be communicatively coupled to, computing device 204 through any individual or combination of physical and/or wireless data coupling components discussed herein. Some attributes of layout(s) 30 and/or modified layout(s) 242 may be converted into a data representation (e.g., a data matrix with several values corresponding to particular attributes) and stored electronically, e.g., within library 280, memory 212 of computing device 204, storage system 214, and/or any other type of data cache in communication with computing device 204.

Images and/or other representations of layout(s) 30 may additionally or alternatively be converted into data inputs or other inputs to layout analysis program 254 with various scanning or extracting devices, connections to independent systems (e.g., library 280), and/or manual entry of a user. As an example, e.g., a user of computing device 204 could manually input layout(s) 30 and/or other forms of information to layout analysis program 254. Layout analysis program 254 of computing device 204 may output modified layout(s) 242, and in some cases may automatically adjust operation of manufacturing tool(s) 260 based on modified layout(s) 242.

Computer system 202 may be operatively connected to or otherwise in communication with manufacturing tool(s) 260 having one or more manufacturing devices configured to construct IC masks from layouts 30 and modified layouts 242, e.g., as instructed by layout adjustment system 220 to produce modified layout(s) 242 from layout(s) 30 as discussed herein. Computer system 202 may be embodied as a unitary device in a semiconductor manufacturing plant coupled to manufacturing tool 260 and/or other devices or may be multiple devices each operatively connected together to form computer system 202. Embodiments of the present disclosure may thereby include using layout analysis program 254 to convert layout(s) 30 into modified layout(s) 242 by identifying structures where further compaction is possible and changing the position of structures to reduce margin size where possible to create modified layout(s) 242. As discussed herein, embodiments of the present disclosure may provide instructions for adjusting manufacturing tool(s) 260 based on modified layout(s) 242, e.g., based on where certain structures are located, modified or removed.

Where computer system 202 includes multiple computing devices, each computing device may have only a portion of layout analysis program 254 and/or layout adjustment system 220 (including, e.g., modules 222, 224, 226, 228) fixed thereon. However, it is understood that computer system 202 and layout adjustment system 220 are only representative of various possible equivalent computer systems that may perform a process described herein. Computer system 202 may obtain or provide data, such as data stored in memory 212 or storage system 214, using any solution. For example, computer system 202 may generate and/or be used to generate data from one or more data stores, receive data from another system, send data to another system, etc.

Referring to FIGS. 3 and 4, various functions of layout adjustment system 220 may be implemented via machine learning module 228 (which may be included within and/or otherwise in cooperation with modules 221), e.g., any mathematical or algorithmic object capable of estimating an unknown function. A neural network is one example of a component that may be implemented as, or within, machine learning module 228. Machine learning module 228 is shown via a schematic diagram to further illustrate processes for proposing modifications to layout(s) 30 according to the disclosure. Machine learning module 228 can relate one or more input variables (e.g., one or more IC layouts 30 contained within, e.g., a library of training data such as library 280) and various parameters within PDK data 230 (including, e.g., threshold margins between structures 32 in layout 30) to generate proposed layout(s) 244 including, e.g., alternative versions of layouts 30 in which structures 32 are in different locations to provide a compacted surface area. Layouts 30 and/or PDK(s) submitted to machine learning module 228 may be manually created, or otherwise may be the results of previous implementations of machine learning and/or other implementations of method 100 discussed herein.

A layer of inputs 282 includes, e.g., input(s) provided by layout(s) 30, PDK data 230, and/or other information transmitted to Layout Adjustment System 220 via I/O interface 210 and/or device 216. Inputs 282 can together define multiple nodes. Each node and respective input 282 may be connected to other nodes in a hidden layer 284, which represents a group of mathematical functions. In embodiments of the present disclosure, inputs 282 can include, e.g., an initial or unmodified form of layout(s) 30 including various structures 32 distributed over a surface area. Each node of hidden layer 284 can include a corresponding weight representing a factor or other mathematical adjustment for converting input variables into output variables. Machine learning module 228 may analyze data in layout(s) 30 and/or PDK data 230 for immediate processing as part of the layer of input(s) 282. However, it is understood that other input(s) from layout(s) 30, PDK(s), data 230, data derived therefrom, and/or information from other sources also may additionally or alternatively be included in hidden layer 284 in other implementations. In embodiments of the disclosure, output 286 from machine learning module 228 can be a proposed layout 244, which may be classified as compliant or non-compliant with design rules for a product to be manufactured. Such classifying may be implemented within the processing structure of machine learning module 228, and/or may be classified externally by other modules 221.

Machine learning module 228 may include, or take the form of, any conceivable machine learning system, and examples of such systems are described herein. In one scenario, machine learning module 228 may include or take the form of an artificial neural network (ANN), and more specifically can include one or more sub-classifications of ANN architectures (e.g., a fully connected neural network, convolutional neural network, recurrent neural network, and/or combinations of these examples and/or other types of artificial neural networks), whether currently known or later developed.

Machine learning module 228 may assist layout adjustment system 220 in generating proposed layouts 244, which may become modified layouts 242 for manufacturing of a product when proposed layouts 244 are compliant with design rules. Proposed layouts 244 in addition or alternatively may be stored in library 280 to assist in analysis of other layout(s) 30 and/or other PDK data 230 regardless of whether proposed layout(s) are selected for manufacture. Machine learning module 228, in some cases, may provide a deep learning framework by actively seeking to reduce the surface area of layouts 30 by extracting and further analyzing proposed layouts 244 that comply with design rules and/or other restrictions, and feeding such proposed layouts 244 into a classifying sub-module within machine learning module 228.

During operation, machine learning module 228 also may extract certain patterns of proposed layouts 244 that comply with design rules, or that are otherwise deemed to be manufacturable. Machine learning module 228 thus is operable for improving the quality of proposed layouts 244 by repeatedly implementing methods of the disclosure. Machine learning module 228 may train and evaluate its framework to generate proposed layout(s) 244 using a variety of performance metrics. Such metrics may include, e.g., surface area reduction, percentage of proposed layouts 244 deemed manufacturable, number of structures 32 below the threshold margin for separation in a manufacturable layout, etc. Library 280 may classify proposed layouts 244 as manufacturable or non-manufacturable in some implementations, and in yet more examples, there may be subclassifications within these categories. Proposed layout(s) 244 can be stored in library 280, or elsewhere (e.g., memory 212) and/or provided as inputs to machine learning module 228 for generating other proposed layouts 244.

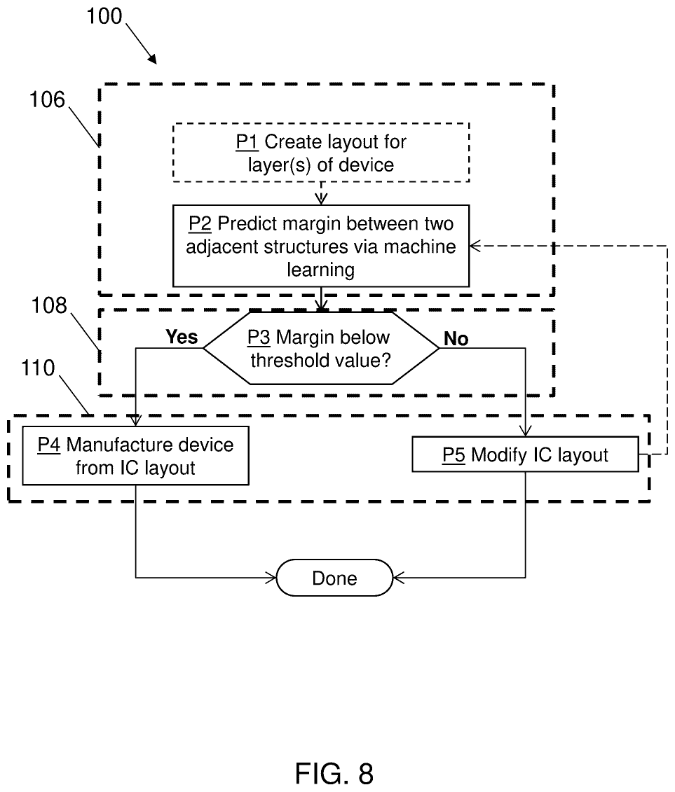

Turning to FIGS. 1, 2, and 6-8 together, illustrative processes are shown for creating modified layout(s) 242 from layout(s) 30, and/or to manufacture a device from layout(s) 30, 242 with more compactness (i.e., less space between structures 32 and hence lower total surface area). The illustrative flow diagram shown in FIG. 8 is an expanded format of the general flow diagram depicted in FIG. 2, and thus represents one possible ordering of processes that together may define operations 106, 108 110 discussed herein. The steps and processes depicted in FIG. 8 may be implemented, e.g., with components of layout analysis program 254, one or more modules 222, 224, 226, 228 of layout adjustment system 220, and/or other components of computer system 202 described herein by example. A single and/or repeated execution of the processes discussed herein may allow for repeated use of manufacturing tool(s) 260 to manufacture masks for various layers and products while providing greater compactness in devices formed from layout(s) 30, 242. In the example processes discussed herein, layout(s) 30 and modified layout(s) 242 generated therefrom will generally be described as including at least two adjacent structures 32, with the total number of adjacent structures 32 differing at each implementation of method 100. That is, each structure 32 under analysis may be compared with one adjacent structure 32 or multiple adjacent structures 32, based on the relevant location in layout 30. It is also understood that the present disclosure may be implemented with respect to multiple structures 32 in layout 30, or on multiple layouts 30 simultaneously and/or sequentially, with each layout's 30 structures 32 having any conceivable dimensions, being in any conceivable number, etc.

As part of operation 106 to predict margin values, method 100 optionally may include process P1 of creating (or otherwise obtaining) layout 30 for one or more layers of a device, e.g., any conceivable device incorporating IC structures therein. Layout 30 may include at least one structure 32 adjacent at least one other structure 32, such that there is separation between the adjacent structures 32 in layout 30. Method 100 is operable to compare such separation with minimum values of separation distance and a threshold margin indicating whether structures 32 may be considered for further compaction. In some implementations, process PI may be implemented before and/or independently of operation 106 and hence may be omitted (i.e., it is shown in dashed lines). Hence, in some cases, process PI may be performed by another party before methods of the disclosure are implemented, in which case any other processes described herein may be implemented on a pre-existing layout 30 without significant differences.

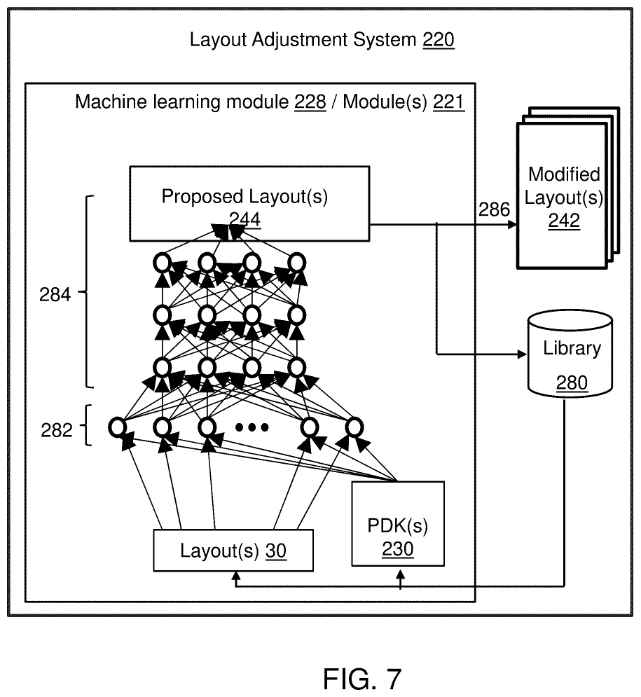

Another phase of operation 106 may include process P2 of predicting the margin between two adjacent structures 32 via machine learning. The predicting generally may correspond with the annotated depiction of layout 30 shown in FIG. 4 and discussed elsewhere herein. That is, process P2 entails predicting the margin (i.e., the sum of a critical dimension, separation distance, and additional separation distance for manufacturability of layout 30) between two structures 32 in layout 30. The predicting in process P2 may include a variety of attributes for a hypothetical product to be manufactured. For instance, such attributes may include, e.g., the actual separation distance, the separation distance required in design rules, the threshold margin for compaction, parasitic resistance and capacitance for structures in layout 30, etc. By implementing process P2, one or more predicted margins between adjacent structures 32 are calculated via machine learning module 228 and its subcomponents (e.g., those shown in FIG. 7 and discussed herein).

Operation 108 (i.e., analyzing the design via layout(s) 30) may be implemented via process P3: determining whether the predicted margin(s) yielded in process P2 are below the threshold margin. As discussed herein, the predicted margin between two structures being greater than the threshold margin indicates that further compaction of structures 32 in layout 30 may be achievable. The determining process P3 may include, e.g., extracting or otherwise identifying all margins predicted for a particular structure in process P2. In the case where none of the predicted margins are below the threshold margin (i.e., “Yes” at process P3), further compaction is not achievable and the method may continue to process P4 of manufacturing a circuit from layout 30. In the case where at least one predicted margin is not below the threshold margin (i.e., “No” at process P3), the method may continue to process P5 of modifying layout 30.

Whether process P4 or process P5 is implemented, each process P4, P5 may encompass operation 110 of modifying layout 30, PDK data 230, and/or manufacturing product(s) from layout 30. Process P4 may include simply using layout 30 or a previously modified layout 242 to create PDK data 230 and causing manufacturing tool(s) 260 to create manufactured product(s) 270 via layout 30 or modified layout(s) 242. Process P5 may include modifying layout 30 to create proposed layout 244 (FIG. 7), e.g., by changing the position of one or more structures 32 in layout 30 (e.g., as shown in FIG. 5 and discussed elsewhere herein). Further, proposed layout 244 may be submitted to library 280 and/or manufacturing tool(s) 260 directly as modified layout 242, or alternatively, may be further analyzed by repeating process P2 and subsequent processes to determine whether further compaction is possible and/or whether modified layout 242 is manufacturable without violating design rules as discussed herein.

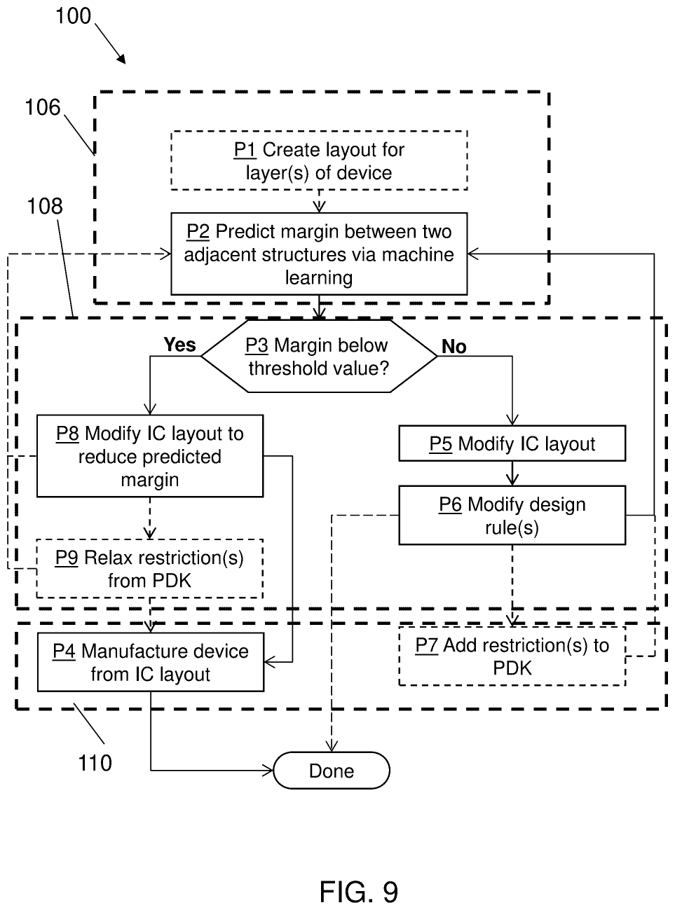

Referring now to FIGS. 1, 2, and 6, 7, and 9 together, further implementations of method 100 may include additional processes and/or sub-processes for further compaction, modification, and/or analysis of layouts 30. According to the FIG. 9 example, operation 106 may include process P2, and optionally process P1, as described elsewhere herein relative to implementations. Operation 108, however, may include any one or more of several additional processes. For instance, in cases where at least one predicted margin is not below the threshold margin (i.e., “No” at process P3), method 100 optionally may include modifying one or more design rules in process P6 in addition to modifying layout in process P5. The modifying of design rules in process P6 may arise from, e.g., two other structures 32 having a larger separation distance as a result of changing the position of one structure 32. This change in separation distance may enable a larger minimum separation distance between two other features, and hence a change to the underlying rules for whether layout 30 is manufacturable.

The proposed layout 244 output from process P6 then may be provided to manufacturing tool(s) 260 and/or library 280 and/or re-analyzed in process P2 similar to other implementations of method 100 discussed herein. In addition, or alternatively, method 100 may include proceeding to operation 110 and adding one or more additional restrictions to PDK data 230. As discussed herein, a “restriction” refers to additional requirements for manufacturability not taking the format of rule(s) 234 in PDK data 230. For instance, the restrictions may include a maximum surface area (e.g., further compaction is required), limitations on how future structures 32 may be moved when generating proposed layout 244 (e.g., other structures 32 cannot be moved to positions nearer to previous locations of a moved structure 32 in layout 30, etc.), relaxing or ignoring minimum margin requirements for certain structures 32, and/or other externally imposed requirements for manufacturability. After adding a new restriction in process P7, the method may continue to process P2, in which the margins are re-predicted and new proposed layout(s) 244 may be generated using the modified layout(s) 242, modified design rules, and/or newly created restrictions in PDK data 230. The various modifications in processes P5, P6, P7 may be stored where appropriate in PDK data 230 as layout data 232, rules field 234, restrictions field 236, and/or elsewhere in memory 212.

In the case where all predicted margins are below the threshold margin (i.e., “Yes” in process P3), method 100 may include process P8 of modifying the IC layout to reduce the predicted margin(s), despite none of the predicted margins being below the threshold margin. Process P8 thus inquires whether further compaction is possible notwithstanding any determination that all margins are below the threshold margin. In process P8, machine learning module 228 may generate one or more proposed layouts 244 (e.g., by moving the location of one or more structures 32) to see if any margins can be reduced without violating design rules for a product. Further processing, in this case, also may include process P9 of accounting for any new restrictions previously added in process P7. For instance, some restrictions in PDK data 230 may prevent layout 30 from being further compacted even when such compaction is possible. Here, machine learning module 228 may generate proposed layout(s) 244 in which one or more restrictions are relaxed (i.e., ignored or modified solely for certain structures 32) and thereafter predicting the margin for such features 32 in proposed layout(s) 244. Where possible, further processing may include process P4 of manufacturing one or more devices from modified layout 242 via manufacturing tool(s) 260. Even where the product in proposed layout(s) 244 is not manufacturable, it may be stored in library 280 and further analysis may be implemented on the non-manufacturable layout (i.e., process P2 may be re-implemented) to identify additional possibilities to make layout 30 more compact.

Embodiments of the disclosure may provide various technical and/or commercial advantages, examples of which are discussed herein. Methods of the disclosure are operable to identify opportunities for reduced surface area in a layout even where all design rules are satisfied, and in addition, methods of the disclosure can identify ways to change the design rules themselves while retaining manufacturability of a product. Machine learning features (e.g., machine learning modules discussed herein) may be provided to enable faster analysis and/or further compaction of new layouts by reference to similar problems addressed in previous layouts and/or products. These benefits, in turn, improve manufacturability and reduce the size of other PDKs.

As will be appreciated by one skilled in the art, aspects of the present disclosure may be embodied as a system, method, or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module,” or “system.” Furthermore, aspects of the present invention may take the form of a computer program product embodied in one or more computer readable medium(s) having computer readable program code embodied thereon.

Any combination of one or more computer readable medium(s) may be used. A computer readable storage medium may be, for example, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that may contain or store a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing. Computer program code for carrying out operations for aspects of the present invention may be written in any combination of one or more programming languages, including an object oriented programming language such as Java, Smalltalk, C++or the like and conventional procedural programming languages, such as the “C” programming language or similar programming languages, e.g., verification languages such as Calibre, ICV, and/or PVS. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described above with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, may be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that may direct a computer, other programmable data processing apparatus, or other devices to function in a particular manner, such that the instructions stored in the computer readable medium produce an article of manufacture including instructions which implement the function/act specified in the flowchart and/or block diagram block or blocks. The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowcharts and block diagrams in the Figures illustrate the layout, functionality, and operation of possible implementations of systems, methods, and computer program products according to various embodiments of the present invention. In this regard, each block in the flowchart or block diagrams may represent a module, segment, or portion of code, which includes one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, may be implemented by special purpose hardware-based systems that perform the specified functions or acts, or combinations of special purpose hardware and computer instructions.

As used herein, the term “configured,” “configured to” and/or “configured for” may refer to specific-purpose patterns of the component so described. For example, a system or device configured to perform a function may include a computer system or computing device programmed or otherwise modified to perform that specific function. In other cases, program code stored on a computer-readable medium (e.g., storage medium), may be configured to cause at least one computing device to perform functions when that program code is executed on that computing device. In these cases, the arrangement of the program code triggers specific functions in the computing device upon execution. In other examples, a device configured to interact with and/or act upon other components may be specifically shaped and/or designed to effectively interact with and/or act upon those components. In some such circumstances, the device is configured to interact with another component because at least a portion of its shape complements at least a portion of the shape of that other component. In some circumstances, at least a portion of the device is sized to interact with at least a portion of that other component. The physical relationship (e.g., complementary, size-coincident, etc.) between the device and the other component may aid in performing a function, for example, displacement of one or more of the device or other component, engagement of one or more of the device or other component, etc.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
identifying a design rule applicable to two adjacent structures represented in an integrated circuit (IC) layout;
predicting, via a machine learning module and an associated library of training data for the IC layout, a margin for the two adjacent structures based on the design rule;
determining whether the predicted margin is below a threshold margin; and
submitting the IC layout to a manufacturing tool in response to the predicted margin being below the threshold margin.

2. The method of claim 1, further comprising modifying the IC layout in response to the predicted margin not being below the threshold margin.

3. The method of claim 1, further comprising:
modifying the design rule in response to the predicted margin not being below the threshold margin; and
repeating the predicting and the determining with the modified design rule.

4. The method of claim 3, further comprising modifying a process design kit (PDK) to include at least one new manufacturing restriction in response to the predicted margin not being below the threshold margin.

5. The method of claim 1, further comprising modifying the IC layout to reduce the predicted margin in response to the predicted margin not being below the threshold margin.

6. The method of claim 5, further comprising modifying a process design kit (PDK) to relax at least one manufacturing restriction in response to the predicted margin being below the threshold margin.

7. The method of claim 1, wherein the library of training data includes at least one of: process design kit (PDK) details for a product group, PDK details for a related product group, manufacturing validation data, and previously predicted margin information.

8. A computer program product stored on a computer readable storage medium, the computer program product comprising program code, which, when being executed by at least one computing device, causes the at least one computing device to:
identify a design rule applicable to two adjacent structures represented in an integrated circuit (IC) layout;
predict, via a machine learning module and an associated library of training data for the IC layout, a margin for the two adjacent structures based on the design rule;
determine whether the predicted margin is below a threshold margin; and
manufacture a device from the IC layout in response to the predicted margin being below the threshold margin.

9. The computer program product of claim 8, further comprising program code for causing the at least one computing device to modify the IC layout in response to the predicted margin not being below the threshold margin.

10. The computer program product of claim 9, further comprising program code for causing the at least one computing device to:
modify the design rule in response to the predicted margin not being below the threshold margin; and
repeat the predicting and the determining with the modified design rule.

11. The computer program product of claim 10, further comprising program code for causing the at least one computing device to modify a process design kit (PDK) to include at least one new manufacturing restriction in response to the predicted margin not being below the threshold margin.

12. The computer program product of claim 8, further comprising program code for causing the at least one computing device to:
modify the IC layout to reduce the predicted margin in response to the predicted margin not being below the threshold margin; and
modify a process design kit (PDK) to relax at least one manufacturing restriction in response to the predicted margin being below the threshold margin.

13. The computer program product of claim 8, wherein the library of training data includes at least one of: process design kit (PDK) details for a product group, PDK details for a related product group, manufacturing validation data, and previously predicted margin information.

14. A system comprising:
a computing device;
an I/O component operatively coupled to the computing device; and
a memory operatively coupled to the computing device,
wherein the computing device includes logic and is configured to perform a method including:
identifying a design rule applicable to two adjacent structures represented in an integrated circuit (IC) layout;
predicting, via a machine learning module and an associated library of training data for the IC layout, a margin for the two adjacent structures based on the design rule;
determining whether the predicted margin is below a threshold margin; and
submitting the IC layout to a manufacturing tool in response to the predicted margin being below the threshold margin.

15. The system of claim 14, wherein the method further includes modifying the IC layout in response to the predicted margin not being below the threshold margin.

16. The system of claim 14, wherein the method further includes:
modifying the design rule in response to the predicted margin not being below the threshold margin; and
repeating the predicting and the determining with the modified design rule.

17. The system of claim 16, wherein the method further includes modifying a process design kit (PDK) for the IC layout to include at least one new manufacturing restriction in response to the predicted margin not being below the threshold margin.

18. The system of claim 14, wherein the method further includes modifying the IC layout to reduce the predicted margin in response to the predicted margin not being below the threshold margin.

19. The system of claim 18, wherein the method further includes modifying a process design kit (PDK) to relax at least one manufacturing restriction in response to the predicted margin being below the threshold margin.

20. The system of claim 14, wherein the library of training data includes at least one of: process design kit (PDK) details for a product group, PDK details for a related product group, manufacturing validation data, and previously predicted margin information.
